(19) United States
(12) Patent Application Publication
(10) Pub. No.: US 2005/0093607 A1
(43) Pub. Date: May 5, 2005

(54) Data transmission circuit and method

(76) Inventors: David Marshall, Fort Collins, CO (US); Karl J. Bois, Fort Collins, IL (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/702,264

(22) Filed: Nov. 5, 2003

(51) Int. Cl. H03L 5/00

(52) U.S. Cl. 327/309

(57) ABSTRACT

A circuit for transmitting data from a transmitter to a receiver is disclosed herein. One embodiment of the circuit may comprise an inverter, a first switch, and a second switch. The input of the inverter is connected to the transmitter. The first switch comprises a control node, wherein current conducts between a first node and a second node depending on the state of the voltage at the control node. The first node is connected to the receiver, the second node is connected to a voltage potential, and the control node is connected to the output of the inverter. The second switch comprises a control node, wherein current conducts between a first node and a second node depending on the state of the voltage at the control node. The first node is connected to the receiver, the second node is connected to the transmitter, and the control node is connected to the output of the inverter.

### BACKGROUND

Many electronic devices, such as integrated circuits, transfer binary data in the form of relatively high and relatively low voltages. As an example, a relatively high voltage may be representative of a binary one and a relatively low voltage may be representative of a binary zero. Many of these electronic devices operate at high frequencies to increase the rate of data transfer. Many of these electronic devices also operate at low power, which means low current is transferred in conjunction with the data transfer. The results are low power devices that are capable of transferring data at high rates.

The combination of low current and high frequency in data transfer makes the data transfer susceptible to errors. For example data transmitted at high frequency and low current is susceptible to voltage fluctuations, such as transient voltages, on the conductor transmitting the data. These voltage fluctuations may cause a voltage representative of a low data value to be erroneously representative of a high data value. Likewise, a voltage representative of a high data value to be erroneously representative of a low data value. When such an event occurs, the data being transmitted is erroneous or corrupt.

Some data conductors or lines are more susceptible to a low data value erroneously being interpreted as a high data value and some data lines are more susceptible to a high data value erroneously being interpreted as a low data value. In addition, voltage fluctuations are typically more prevalent on longer data lines. For example a long data line in an integrated circuit may be more susceptible to voltage fluctuations than a short data line.

### SUMMARY

A circuit for transmitting data from a transmitter to a receiver is disclosed herein. One embodiment of the circuit may comprise an inverter, a first switch, and a second switch. The input of the inverter is connected to the transmitter. The first switch comprises a control node, wherein current conducts between a first node and a second node depending on the state of the voltage at the control node. The first node is connected to the receiver, the second node is connected to a voltage potential, and the control node is connected to the output of the inverter. The second switch comprises a control node, wherein current conducts between a first node and a second node depending on the state of the voltage at the control node. The first node is connected to the receiver, the second node is connected to the transmitter, and the control node is connected to the output of the inverter.

### BRIEF DESCRIPTION OF THE DRAWINGS

FIG. 1 is a block diagram of an embodiment of a circuit for transmitting data to a receiver that is sensitive to high voltage fluctuations.

FIG. 2 is a schematic diagram of an embodiment of a circuit for transmitting data to a receiver that is sensitive to high voltage fluctuations.

FIG. 3 is a block diagram of an embodiment of a circuit for transmitting data to a receiver that is sensitive to low voltage fluctuations.

FIG. 4 is a schematic diagram of an embodiment of a circuit for transmitting data to a receiver that is sensitive to low voltage fluctuations.

### DETAILED DESCRIPTION

In summary, the circuits and methods disclosed herein reduce the susceptibility of data errors caused by voltage fluctuations on data lines or conductors that transmit data. The voltage fluctuations may be the result of transients or noise on the data lines. Data transmissions originate at a location that is not proximate a receiver. The data is processed and transmitted via a first data line to a switching circuit proximate a receiver circuit that receives the data. A second data line transmits a signal from the switching circuit to the area proximate the data origination. Signals on the second data line serve to maintain the voltage on the first data line until the voltage is changed by the transmitter. Accordingly, the data transmission is less susceptible to voltage fluctuations on the first data line.

Having summarily described an embodiment of the circuits and methods, they will now be described in greater detail.

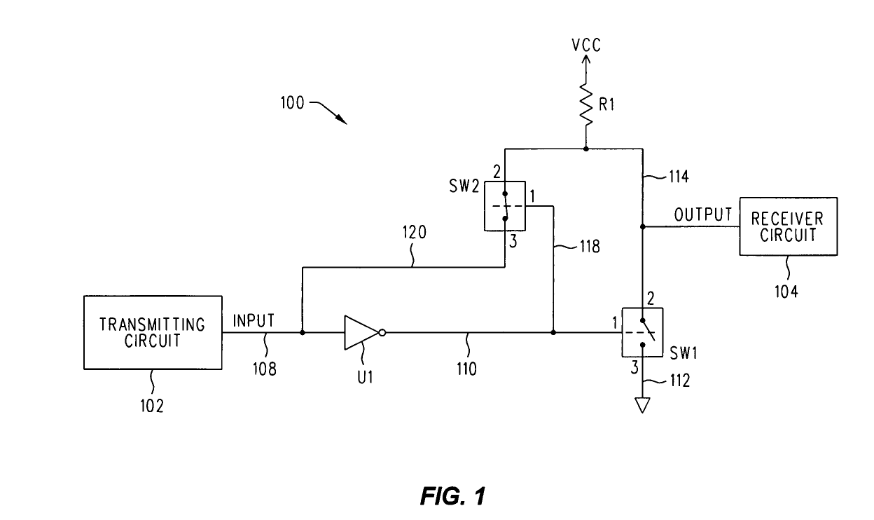

FIG. 1 is a block diagram of an embodiment of a circuit 100 for transmitting data to a receiver circuit 104 that is sensitive to high voltage fluctuations. More specifically, the receiver circuit 104 is susceptible to low voltage data transmissions being erroneously interpreted as high voltage data transmissions. More specifically, the receiver circuit 104 is susceptible to erroneously detecting a high voltage when a low voltage was transmitted from the transmitter circuit 102.

The circuit 100 may comprise an inverter U1, a first switch SW1, and a second switch SW2. The inverter U1 is an example of an electronic device that inverts an output voltage relative to an input voltage. Other embodiments of the inverter U1 may be used in the circuit 100, such as a transistor or an operational amplifier, neither of which are shown herein. In the embodiment of the circuit 100 of FIG. 1, the first switch SW1 is normally open and the second switch SW2 is normally closed. More specifically, with reference to the first switch SW1, current only flows between nodes 2 and 3 when a voltage is applied to node 1, which is sometimes referred to as the control node. With reference to the second switch SW2, current flows between node 2 and 3 unless a voltage is applied at node 1, which is also a control node. Other embodiments of the switches SW1 and SW2 will be described in greater detail below with reference to other embodiments of the circuit 100.

The input of the inverter U1 is connected to the transmitter circuit 102 via a line 108. Lines, as used herein, may be any conductor, such as traces on a printed circuit board or an integrated circuit, that transmit data. The output of the inverter U1 is connected to node 1 of the first switch SW1 via a line 110. Node 3 of the first switch SW1 is connected to ground via a line 112. In other embodiments of the circuit 100, node 3 of the first switch SW1 may be connected to other preselected potentials. For example, node 2 may be connected to high or low voltages.

Node 2 of the first switch SW1 is connected to an output of the circuit 100, which is the input of the receiver circuit 104, via a line 114. Node 2 of the first switch SW1 is also connected to node 2 of the second switch SW2 via the line 114. Node 1 of the second switch SW2 is connected to node 1 of the first switch SW1 via a line 118. Node 3 of the second switch SW2 is connected to the input of the inverter via a line 120. In the embodiment of the circuit 100 of FIG. 1, a pull up resistor R1 is connected between VCC and the line 114. It should be noted that some embodiments of the circuit 100 may function without the pull up resistor R1.

In the circuit 100 of FIG. 1, the lines 110 and 120 may be relatively long. For example, the lines 110 and 120 may cross a substantial portion of a circuit board or an integrated circuit, neither of which are shown herein. The inverter U1 may be located proximate the transmitter circuit 102. The first switch SW1 and the second switch SW2 may be located proximate the receiver circuit 104.

Having described the components of the circuit 100, the operation of the circuit 100 will now be described.

The transmitter circuit 102 generates binary data that is transmitted to the input of the circuit 100. The binary data consists of a plurality of low and high voltages, wherein a low voltage may be representative of a binary zero and a high voltage may be representative of a binary one. When the transmitter circuit 102 outputs a high voltage, the high voltage is present at the input of the inverter U1. Therefore, the output of the inverter U1 on the line 110 is a low voltage. The low voltage on the line 110 maintains the first switch SW1 in an open position and the second switch SW2 in a closed position. The output of the circuit 100 and, thus, the input to the receiver circuit 104 is pulled high by the pull up resistor R1. The high voltage is also conducted to the input of the inverter U1 via the line 120. Therefore, the line 110 is maintained low and the circuit 100 remains stable. As set forth above, the pull up resistor R1 may not be required. For example, the input voltage at the receiver circuit 104 may float high without being required to be pulled high.

The circuit 100 and all the circuits described herein have lines 110, 120 operatively connected between the transmitter circuit 102 and the receiver circuit 104. The voltages on the lines 110 and 120 are the inverse of one another and serve to stabilize the circuit 100. For example, when the voltage on the line 110 is low, the voltage on the line 120 is high. The high voltage on the line 120 serves to maintain the voltage on the line 110 low. Accordingly, transients caused by noise or other sources that would otherwise pull the voltage on the line 110 high are less likely to do so. Thus, the transmission of data between the transmitting circuit 110 and the receiver circuit is less susceptible to errors caused by transients, such as noise.

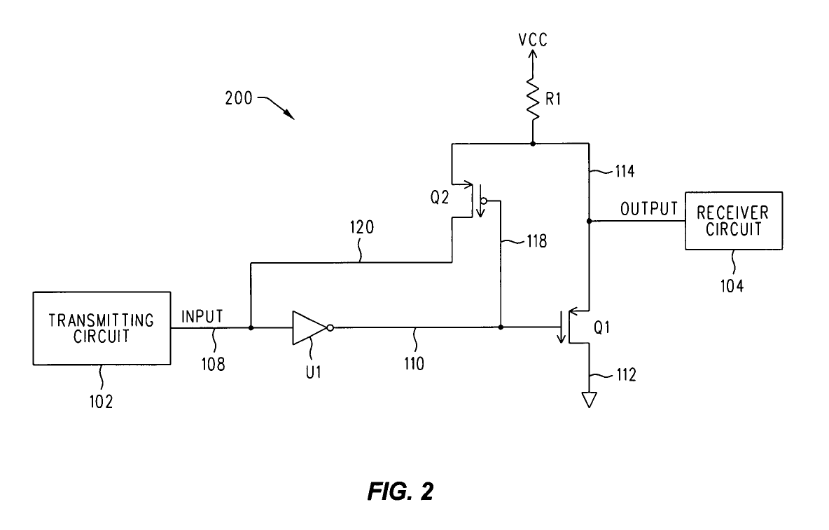

A circuit 200 representative of an embodiment of the block diagram of FIG. 1 is shown in FIG. 2. As with the block diagram of FIG. 1, the circuit 200 is an embodiment of a circuit for transmitting data from the transmitter circuit 102 to the receiver circuit 104. The circuit 200 may be a portion of a larger circuit located on a circuit board or it may be a portion of an integrated circuit, neither of which are shown herein.

The circuit 200 includes the inverter U1, an N-FET, referred to as FET Q1, and a P-FET, referred to as FET Q2. The circuit 200 uses the FET Q1 rather than the switch SW1 of FIG. 1. The circuit 200 also uses the FET Q2 rather than the switch SW2 of FIG. 1. The FETs Q1 and Q2 are embodiments of switching devices. In other embodiments of the circuit 100, other switching devices may be used. For example, solid state switching devices or bipolar junction transistors may be used in place of one or both of the FETs Q1 and Q2.

The input of the inverter U1 is connected to the transmitter circuit 102 via the line 108. The output of the inverter U1 is connected to the gate of the FET Q1 via the line 110. The drain of the FET Q1 is connected to ground via the line 112 and the source of the FET Q1 is connected to an output of the circuit 200 via the line 114. As set forth above, the output of the circuit 200 is the input to the receiver circuit 104. The source of the FET Q1 is connected to the source of a FET Q2 via the line 114. The gate of the FET Q1 is connected to the gate of the FET Q2 by way of the line 118. The drain of the FET Q2 is connected to the input of the inverter U1 by way of the line 120.

Having described the components of the circuit 200, the operation of the circuit 200 will now be described. When the transmitter circuit 102 outputs a high voltage to the input of the circuit 200 on the line 108, the voltage on the line 110 is forced low by the inverter U1. This low voltage on the line 110 causes the FET Q1 to turn off and the FET Q2 to turn on. Accordingly, the output of the circuit 200, which is the input to the receiver circuit 104 is high. Thus, a high voltage is output by the transmitter circuit 102 and received by the receiver circuit 104, but a low voltage is transmitted between the circuits.

The opposite occurs when the transmitter circuit 102 outputs a low voltage on the line 108 to the input of the circuit 200. The low voltage on the line 108 causes the inverter U1 to output a high voltage on the line 110. This high voltage on the line 110 causes the FET Q1 to turn on and the FET Q2 to turn off. When the FET Q1 is turned on, the voltage on the line 114 is pulled low by the connection of the drain of the FET Q1 to ground or a low voltage potential. Accordingly, the voltage at the output of the circuit 200 and the input to the receiver circuit 104 is low. The voltage on the line 120 remains high, which keeps the inverter U1 outputting a low voltage on the line 110.

The circuit 200 overcomes problems of transmitting data when the transmission is sensitive to low voltages erroneously becoming or interpreted as high voltages. For example, transients caused by noise and other sources are less likely to cause erroneous data transfers in the circuit 200 than they are with conventional data transmission circuits. Rather than solely transmit a low voltage along the distance of the line 110, a high voltage is also transmitted between the output of the inverter U1 and the gates of the FET Q1 and the FET Q2. As described above, the inverter U1 is located proximate the transmitter circuit 102 and the FETs Q1 and Q2 are located proximate the receiver circuit 104. The FET Q1 changes the low voltage on the line 110 to a high voltage at the output of the circuit 200. Thus, the input and output of the circuit 200 have approximately the same voltage.

As set forth above, the circuit 200 serves to reduce transients and other voltage fluctuations from causing erroneous data from being transmitted. When the voltage on the line 110 is high, the voltage on the line 120, which is the input to the inverter U1, is forced low. Thus, the line 110 is maintained in a high state by the inverter U1 and the voltage on the line 120. In turn, data transmissions between the transmitter circuit 102 and the receiver circuit 104 are less likely to be affected by transients and other voltage fluctuations.

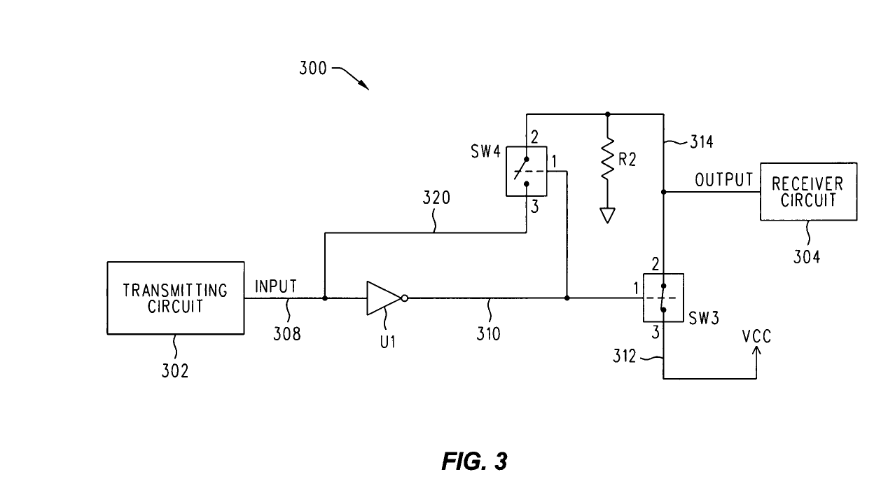

Having described embodiments of circuits that overcome problems of transmitting data when the transmission is sensitive to low voltages becoming high, embodiments of circuits that overcome problems of transmitting high voltages will now be described. An embodiment of such a circuit is shown by the block diagram in FIG. 3 of a circuit 300.

As with the circuit 100 of FIG. 1, the circuit 300 has a transmitter circuit 302 and a receiver circuit 304. The transmitter circuit 302 and the receiver circuit 304 may not be located proximate one another. The circuit 300 includes the inverter U1, a switch SW3, a switch SW4, and a pull down resistor R2. As with the circuit 100 of FIG. 1, the pull down resistor R2 may not be required. The inverter U1 of FIG. 3 may be the same type of device as shown in FIGS. 2 and 3. The switch SW3 is normally closed and may be the same type of switching device as the switch SW2 of FIG. 1. The switch SW4 is normally open and may be the same type of switching device as the switch SW1 of FIG. 1.

The circuit 300 has an input at a line 308, which is connected to the input of the inverter U1. The output of the inverter U1 is connected to a line 310. The line 310 is connected to node 1 of the switch SW3 and node 1 of the switch SW4. Node 1 of the switch SW3 and node 1 of the switch SW4 are sometimes referred to as the control nodes. Node 3 of the switch SW3 is connected to VCC or another preselected high voltage via a line 312. Node 2 of the switch SW3 is connected to a line 314, which serves as the output of the circuit 300 and the input of the receiver circuit 304. The line 314 is also connected to node 2 of the switch SW4. The pull down resistor R2 is connected between the line 314 and ground. Node 3 of the switch SW4 is connected to the input of the inverter U1 via a line 320.

Having described the components of the circuit 300, its operation will now be described. When the transmitter circuit 102 outputs a low voltage on the line 308, the inverter U1 causes the voltage on the line 310 to go high. This high voltage on the line 310 causes the switch SW3 to open and the switch SW4 to close. When the switch SW3 is open and the switch SW4 is closed, the voltage at the output of the circuit 300 is pulled low by the pull down resistor R2. In addition, the low voltage on the line 320, which is the same voltage as the output of the circuit 300 is conducted to the output of the circuit 300. Accordingly, the voltage on the line 310 remains stable until it is caused to be changed by the transmitter circuit 302.

When the transmitter 302 outputs a high voltage on the line 308, the inverter U1 causes the voltage on the line 310 to go low. This low voltage on the line 310 causes the switch SW3 to close and the switch SW4 to open. When the switch SW3 is closed, VCC is conducted to the output of the circuit 300 and, thus, to the receiver circuit 304. Accordingly, both the output of the transmitter circuit 102 and the input to the receiver circuit 104 are at the same potential.

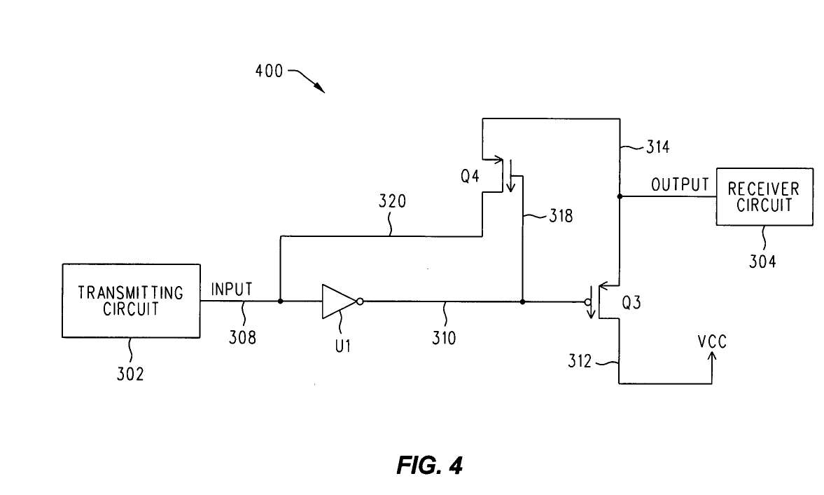

A more detailed embodiment of the circuit 300 is provided in FIG. 4 by a circuit 400. The circuit 400 comprises the inverter U1, a P-FET, referred to as the FET Q3, and an N-FET, referred to as the FET Q4. The circuit 400 uses the FET Q3 rather than the switch SW3 of FIG. 3. The circuit 400 also uses the FET Q4 rather than the switch SW4 of FIG. 3. It should be noted that the circuit 400 is substantially the opposite of the circuit 200 of FIG. 2.

The input of the inverter U1 is connected to the transmitter circuit 302 via the line 308. The output of the inverter U1 is connected to the gate of the FET Q3 via the line 310. The source of the FET Q3 is connected to VCC or another preselected high voltage potential via the line 312. The drain of the FET Q3 is connected to the output of the circuit 400 via the line 314, which is the input to the receiver circuit 304. The drain of the FET Q3 is also connected to the source of the FET Q4 via the line 314. The gate of the FET Q3 is connected to the gate of the FET Q4 by way of the line 318. The drain of the FET Q4 is connected to the input of the inverter U1 by the line 320.

Having described the components of the circuit 400, its operation will now be described. The circuit 400 operates in a substantial opposite manner as the circuit 200, FIG. 2, wherein the voltage levels are opposite. When the transmitter circuit 302 outputs a high voltage on the line 308, the inverter U1 causes the voltage on the line 310 to go low. The low voltage on the line 310 causes the FET Q3 to turn on, which causes the voltage VCC, which is high, to be present at the output of the circuit 400 and the input to the receiver circuit 304. The high voltage on the line 310 causes the FET Q4 to turn off. Accordingly, the high voltage generated by the transmitter circuit is transmitted to the proximity of the receiver circuit 304 as a low voltage.

The opposite occurs when the transmitter circuit 302 outputs a low voltage on the line 308. The inverter U1 causes the voltage on the line 310 to go high. The high voltage on the line 310 causes the FET Q3 to turn off, which causes a low voltage to be present at the output of the circuit 400 and the input to the receiver circuit 304. The high voltage on the line 310 causes the FET Q4 to turn on, which maintains the low voltage at the input to the receiver circuit 304. Accordingly, the low voltage generated by the transmitter circuit is transmitted to the proximity of the receiver circuit 304 as a high voltage. Furthermore, the voltage at the output of the transmitter circuit 302 is the same as the voltage at the input of the receiver circuit 304.

1. A circuit for transmitting data from a transmitter to a receiver, said circuit comprising:
an inverter, wherein the input of said inverter is connected to said transmitter;
a first switch comprising a control node, wherein current may conduct between a first node and a second node depending on the state of the voltage at said control node, wherein said first node is connected to said receiver, wherein said second node is connected to a voltage potential, and wherein said control node is connected to the output of said inverter; and
a second switch comprising a control node, wherein current may conduct between a first node and a second node depending on the state of the voltage at said control node, wherein said first node is connected to said receiver, wherein said second node is connected to said transmitter, and wherein said control node is connected to the output of said inverter.

2. The circuit of claim 1, wherein said potential is approximately ground.

3. The circuit of claim 1, wherein said potential is approximately VCC.

4. The circuit of claim 1, wherein said first switch is a FET.

5. The circuit of claim 1, wherein said second switch is a FET.

6. The circuit of claim 1, wherein said potential is approximately ground, wherein said first switch is an N-FET, wherein said control node of said first switch is the gate of said N-FET, wherein said first node of said first switch is the source of said N-FET, and wherein the second node of said first switch is the drain of said N-FET.

7. The circuit of claim 1, wherein said potential is approximately ground, wherein said second switch is a P-FET, wherein said control node of said second switch is the gate of said P-FET, wherein said first node of said second switch is the drain of said P-FET, and wherein said second node of sais second switch is the source of said P-FET.

8. The circuit of claim 1, wherein said potential is approximately VCC, wherein said first switch is a P-FET, wherein said control node of said first switch is the gate of said P-FET, wherein said first node of the of said first switch is the drain of said P-FET, and wherein said second node of said first switch is the drain of said P-FET.

9. The circuit of claim 1, wherein said potential is approximately VCC, wherein said second switch is an N-FET, wherein said control node of said second switch is the gate of said N-FET, wherein said first node of said second switch is the source of said N-FET, and wherein said second node of said second switch is the drain of said N-FET.

10. A method for transmitting data from a transmitter to a receiver, said method comprising:
inverting said data using an inverter, said inverter comprising an input and an output;
toggling a first switch depending on the state of the output of said inverter, said first switch comprising a first node and a second node, said first node of said first switch being connected to said receiver and said second node of said first switch being connected to a preselected potential; and
toggling a second switch depending on the state of the output of said inverter, said second switch comprising a first node and a second node, said first node of said first switch being connected to said receiver and said second node of said first switch being connected to said input of said inverter.

11. The method of claim 10, wherein said first switch is an N-FET, wherein said preselected potential is approximately ground, and wherein said toggling a first switch comprises:
turning said N-FET on when the output of said transmitter is a low potential; and
turning said N-FET off when the output of said transmitter is a high potential.

12. The method of claim 10, wherein said first switch is a P-FET, wherein said preselected potential is high, and wherein said toggling a first switch comprises:
turning said P-FET on when the output of said transmitter is a high potential; and
turning said P-FET off when the output of said transmitter is a low potential.

13. The method of claim 10, wherein said second switch is a P-FET, wherein said preselected potential is approximately ground, and wherein said toggling a second switch comprises:
turning said P-FET off when the output of said transmitter is a low potential; and
turning said P-FET on when the output of said transmitter is a high potential.

14. The method of claim 10, wherein said second switch is an N-FET, wherein said preselected potential is high, and wherein said toggling a first switch comprises:
turning said N-FET on when the output of said transmitter is a high potential; and
turning said N-FET off when the output of said transmitter is a low potential.

15. A method of transmitting data from a transmitter to a receiver, said method comprising:
inverting a first data signal from said transmitter using an inverter;
transmitting the inverted data signal to a first switch and a second switch;
inverting said inverted data signal using said first switch, wherein the second inverted data signal is transmitted to said receiver;
generating a second data signal at said second switch, wherein said second data signal is substantially similar to said first data signal; and
transmitting said second data signal to the input of said inverter.

16. A circuit for transmitting data from a transmitter to a receiver, said circuit comprising:
an inverting means for inverting a data signal, said inverting means comprising an input and an output, wherein said input is connected to said transmitter;
a first switching means for conducting voltages to said receiver, said switching means comprising a control node that is connected to the output of said inverting means; and
a second switching means for conducting voltages to the input of said inverting means, said second switching means comprising a control node that is connected to the output of said inverting means.

17. The circuit of claim 16, wherein said first switching means is for conducting either a high voltage or a low voltage to said receiver and wherein the voltage conducted to said receiver is the opposite of a voltage present at said control node of said first switching means.

18. The circuit of claim 16, wherein said second switching means is for conducting either a high voltage or a low voltage to the input of said inverting means and wherein the voltage conducted to the input of said inverting means is the opposite of a voltage at the output of said inverting means.
